(19) United States
(12) Patent Application Publication
(10) Pub. No.: US 2010/0258873 A1
(43) Pub. Date: Oct. 14, 2010

(54) SEMICONDUCTOR DEVICE AND METHOD OF MANUFACTURING THE SAME

(75) Inventors: KEIICHI HARASHIMA, KANAGAWA (JP); Hiroyuki Maeda, Tokyo (JP)

Correspondence Address: YOUNG & THOMPSON, 209 Madison Street, Suite 500, Alexandria, VA, 22314, US

(73) Assignees: NEC ELECTRONICS CORPORATION, KANAGAWA (JP); KABUSHIKI KAISHA TOSHIBA, TOKYO (JP)

(21) Appl. No.: 12/756,399

(22) Filed: Apr. 8, 2010

(30) Foreign Application Priority Data
Apr. 9, 2009 (JP) 2009-095295

(51) Int. Cl. H01L 27/088; H01L 21/8234; H01L 21/308; H01L 21/3065

(52) U.S. Cl. 257/368; 438/689; 438/734; 438/712; 257/E27.06; 257/E21.627; 257/E21.231; 257/E21.218

(57) ABSTRACT

A semiconductor device includes a first contact formed so as to be connected to the first impurity-diffused region, but not to the first gate electrode; and a second contact formed so as to be connected commonly to the second gate electrode and the second impurity-diffused region, wherein each of the first contact and the second contact has a profile such that the taper angle changes at an intermediate position in the depth-wise direction from the surface of an insulating film towards a substrate, and the intermediate position where the taper angle changes resides more closer to the substrate in the second contact, than in the first contact.

This application is based on Japanese patent application No. 2009-095295, the content of which is incorporated hereinto by reference.

### BACKGROUND

1. Technical Field

The present invention relates to a semiconductor device and a method of manufacturing the same.

2. Related Art

With recent advances in shrinkage of semiconductor devices, a space between the adjacent gate electrodes has been becoming narrower. Accordingly, in an exemplary case where a contact is formed between the adjacent gate electrodes in order to connect a low-resistivity diffusion layer which is formed in the surficial portion of a semiconductor substrate between these gate electrodes, typically with an upper interconnect, and where it is desired to form a contact hole while avoiding electrical connection between the contact and the gate electrodes, a risk of short-circuiting of an electro-conductive material filled in the contact hole with the gate electrode has been becoming larger. In view of avoiding this sort of short-circuiting, it may therefore be necessary to shrink the diameter of the contact hole. However, efforts of shrinking area of opening of a resist pattern in a well controlled manner using a lithographic process, so as to satisfy demands for further shrinkage of devices, may be obstructed by a technical limit. For example, there may be a case where contact holes having a diameter of 40 nm or around are necessarily formed, even if a lithographic process adopted thereto is characterized by a lower limit of the diameter of opening of 60 to 70 nm. In this case, it is necessary to form the contact holes according to an etching condition, under which the diameter of the contact holes may gradually be reduced in the course of etching.

Published Japanese Translation of PCT International Publication for Patent Application No. 2007-505492 describes a technique of etching a material layer through a resist pattern formed thereon, so as to obtain a pattern of the material layer shrunk from the size of opening of the resist pattern.

On the other hand, SRAM (Static Random Access Memory) for example adopts a shared contact, by which a diffusion layer and a gate electrode may be connected through a single contact hole. The shared contact refers to a structure in which a portion connected to both of the diffusion layer and the gate electrode is provided in a single contact hole, and is used for the purpose of achieving the shrinkage of the device and lowering in resistivity of the contact. The shared contact needs at least a certain degree of area in a plan view, sufficient for ensuring contact regions with the gate electrode and the diffusion layer. Unlike a general contact having a nearly circular geometry (converted from a square geometry in a mask pattern) in a plan view, the shared contact has an elliptic geometry, and therefore has a larger area in the plan view, than the general contact has.

Since the general contact and the shared contact are different in the planar area as described in the above, so that the areas of opening of the contact holes for forming these contacts are different from each other. As a consequence, a problem arises typically in that local difference in etching rates may occur, in the process of forming both of the general contact and the shared contact at the same time.

Japanese Laid-Open Patent Publication No. 2008-124133 describes a technique of concomitantly forming a contact hole brought into contact with a diffusion layer between the adjacent gate electrodes, and a shared contact hole brought into contact with both of the gate electrode and the diffusion layer. In this technique, a first liner film and a second liner film are formed in a stacked manner in an area where a shared contact is formed. According to the description, the configuration successfully prevents extra etching in the shared contact region.

Japanese Laid-Open Patent Publication No. H05-283374 describes a technique of forming a small-diameter contact hole and a large-diameter contact hole in an insulating interlayer, by a two-step etching process using a higher fluorocarbon compound, in which proper-depth etching and extra etching are executed. In this case, a first contact hole having a smaller diameter tends to have an excessive amount of carbonaceous polymers deposited therein due to degraded efficiency of removal by combustion, causes tapering of the sidewall thereof and decrease in the etching rate, to thereby leave an unetched portion as a residue. According to the description of the publication, the deposition of the carbonaceous polymers is enhanced only to a degree not so accelerative to the loading effect by reducing the content of O₂ in the step of extra etching, and energy of incident ion is reduced by lowering the RF power density. The strategy is aimed at removing the residue in the first contact hole having a smaller diameter, by elevating the selectivity to the lower interconnect so as to reduce any possible damages.

### SUMMARY

It has, however, been difficult to form the contact holes for general contact and shared contact at the same time, while avoiding short-circuiting between the general contact and the gate electrode, and also while ensuring a sufficient area of contact region with the gate electrode and the diffusion layer in the shared contact as will be explained later referring to FIG. 6.

According to the present invention, there is provided a semiconductor device which includes:

a substrate;

a first gate electrode formed over the substrate, while placing a gate insulating film in between;

a second gate electrode formed over the substrate, while placing a gate insulating film in between;

a first impurity-diffused region formed by the side of the first gate electrode;

a second impurity-diffused region formed by the side of the second gate electrode;

an insulating film formed over the entire surface of the substrate over the first gate electrode and the second gate electrode;

a first contact formed in the insulating film, so as to be connected to the first impurity-diffused region, but not to the first gate electrode; and

a second contact formed in the insulating film, so as to be connected commonly to the second gate electrode and the second impurity-diffused region.

Each of the first contact and the second contact has a profile such that the taper angle changes at an intermediate position in the depth-wise direction from the surface of the insulating film towards the substrate, and the intermediate position where the taper angle changes resides more closer to the substrate in the second contact, than in the first contact.

According to the present invention, there is also provided a method of manufacturing a semiconductor device having a first gate electrode and a second gate electrode formed over a substrate, while placing a gate insulating film in between, respectively; a first impurity-diffused region formed by the side of the first gate electrode; a second impurity-diffused region formed by the side of the second gate electrode; and an insulating film formed over the entire surface of the substrate over the first gate electrode and the second gate electrode.

The method includes:

forming, over the insulating film, a resist film which has a first opening through which a first contact hole in which a first contact is to be formed so as to be connected to the first impurity-diffused region, but not to the first gate electrode; and has a second opening through which a second contact hole in which a second contact is to be formed so as to be connected commonly to the second gate electrode and the second impurity-diffused region, and

etching the insulating film, using the resist film as a mask, to thereby form the first contact hole and the second contact hole in the insulating film,

in the etching the insulating film, the etching being firstly performed according to a first etching condition and then in the course of the etching, the first etching condition being changed to a second etching condition under which the diameter of hole is more likely to be shrunk towards the substrate, as compared with the first etching condition.

According to the configuration, difference between the area of opening of the opening in a resist film for forming the contact hole and the area of opening at the bottom of the contact hole (referred also to as “process-related conversion”) may be reduced in the second contact given as a shared contact. In this way, a margin for short-circuiting between the first contact and the first gate electrode may be expanded, while ensuring a sufficient area of contact region of the second contact with respect to the second impurity-diffused region and the second gate electrode, even if the first contact is necessarily formed particularly between a plurality of first gate electrodes narrowly spaced from each other. Stability of yield of the semiconductor device may therefore be improved.

In addition, since the first contact hole and the second contact hole may be formed at the same time by a single photolithographic process, the number of processes may be prevented from increasing, and thereby the cost of manufacturing may be suppressed. Also the cell area may be prevented from increasing.

Note that all arbitrary combinations of the above-described constituents, and all exchanges of expressions of the present invention among method, device and so forth are valid as embodiments of the present invention.

According to the present invention, both of the general contact and the shared contact may be allowed to have desirable contact characteristics, while suppressing the number of processes of manufacturing from increasing.

### BRIEF DESCRIPTION OF THE DRAWINGS

The above and other objects, advantages and features of the present invention will be more apparent from the following description of a certain preferred embodiment taken in conjunction with the accompanying drawings, in which:

FIG. 1 is a plan view illustrating a configuration of a semiconductor device in one embodiment of the present invention;

FIG. 2 is a sectional view illustrating a configuration of the semiconductor device in the embodiment of the present invention;

FIGS. 3 to 5 are sectional views illustrating steps of manufacturing the semiconductor device in the embodiment of the present invention; and

FIG. 6 is a sectional view explaining a problem when forming the contact holes for general contact and shared contact at the same time.

### DETAILED DESCRIPTION

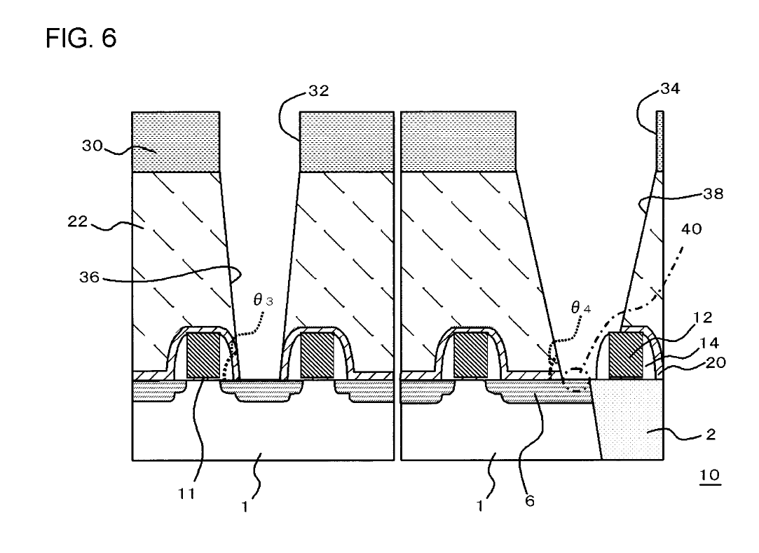

Before describing of the present invention, the related art will be explained in detail with reference to FIG. 6 in order to facilitate the understanding of the present invention.

A semiconductor device 10 contains a substrate 1, a device isolation region 2 and impurity-diffused regions 6 (diffusion layers) formed in the substrate 1, and a gate insulating film 11, gate electrodes 12, sidewalls 14, a cover insulating film 20, and an insulating interlayer 22 formed over the substrate 1. The cover insulating film 20 and the insulating interlayer 22 are formed to cover the impurity-diffused regions 6 and the gate electrodes 12.

Paragraphs below will explain procedures of concomitantly forming a general contact hole and a shared contact hole at the same time in the thus-configured semiconductor device 10, according to an etching condition under which the diameter of the contact holes gradually shrinks. First, a resist film 30 having an opening 32 and an opening 34 formed therein is formed over the insulating interlayer 22, and the insulating interlayer 22 and the cover insulating film 20 are etched using the resist film 30 as a mask. The opening 32 herein is an opening pattern used for forming the general contact hole, whereas the opening 34 is an opening pattern used for forming the shared contact hole. The opening 34 has an area of opening larger than that of the opening 32.

In the process of forming the contact holes according to an etching condition under which the diameter of the contact holes gradually shrinks in the course of etching, a larger contact hole tends to have a smaller taper angle. In other words, the contact hole 38 will have a smaller taper angle than the contact hole 36 will have. The taper angle herein is defined by the angle formed between the surface of the substrate 1 and the sidewall of the contact hole, on the insulating interlayer 22 side (smaller than or equal to 90°. In the illustrated example, taper angle θ₄ of the contact hole 38 is smaller than taper angle θ₃ of the contact hole 36. As a consequence, difference between the area of opening of the opening (34 or 32) in the resist film 30 and the area of opening at the bottom of the contact hole (referred to as “process-related conversion”, hereinafter) will be larger in the contact hole 38 having a larger area of opening, than in the contact hole 36.

More specifically, the area of the bottom of the contact hole 38 may occasionally be too small to ensure a sufficient area of contact region 40 with the gate electrode 12 and the diffusion layer 6, necessary for the shared contact. On the other hand, an effort of etching according to an etching condition under which the taper angle will expectedly be large, may produce a too large area of the bottom of the general contact, and thereby it may be difficult to prevent short-circuiting between the general contact and the gate electrodes. Alternatively, if the contact hole 36 and the contact hole 38 are desired to be formed independently according to different etching conditions, lithographic process for forming the pattern will necessarily be repeated twice, and this increases the number of processes and consequently increases costs of the semiconductor device.

In addition, increase in the area of opening of the opening 34 inevitably increases the cell area, and is therefore disadvantageous in pursuit of higher degree of integration of devices.

The invention will now be described herein with reference to an illustrative embodiment. Those skilled in the art will recognize that many alternative embodiments can be accomplished using the teachings of the present invention and that the invention is not limited to the embodiment illustrated for explanatory purposes.

One embodiment of the present invention will be explained referring to the attached drawings. Note that all similar constituents in all drawings are given similar reference numerals or symbols, explanations of which will not always necessarily be repeated.

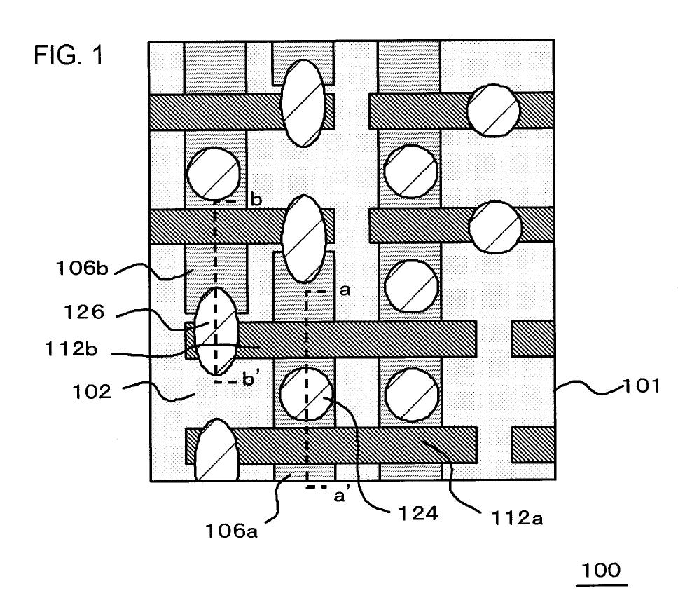

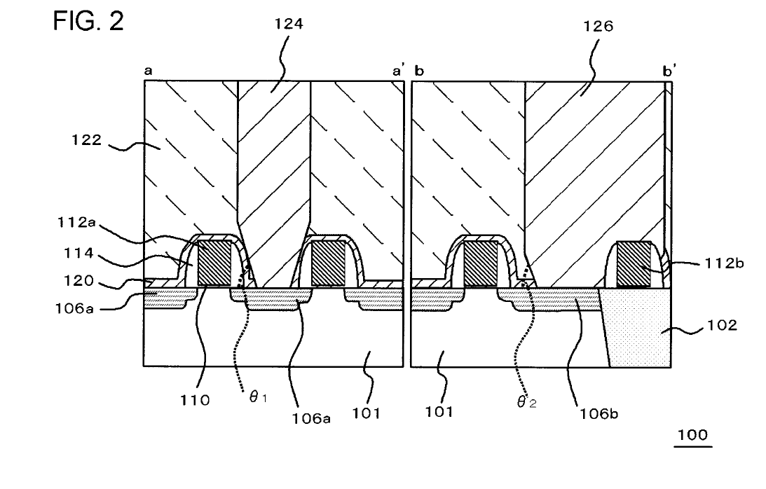

FIG. 1 is a plan view illustrating a configuration of a semiconductor device of this embodiment. FIG. 2 is a sectional view taken along lines a-a′ and b-b′ in FIG. 1.

A semiconductor device 100 has a substrate 101, a device isolation region 102 formed in the substrate 101, first impurity-diffused regions 106a and second impurity-diffused regions 106b partitioned by the device isolation region 102 and gate electrode structures, gate insulating films 110 formed over the substrate 101, and first gate electrodes 112a and second gate electrodes 112b formed over the substrate 101 while respectively placing the gate insulating film 110 in between. The first impurity-diffused regions 106a and the second impurity-diffused regions 106b are formed by ion implantation of dopants, using the gate electrodes (or substitutive dummy structures) as a mask, and succeeding annealing for activation, while leaving the surface of the device isolation region 102 as an insulating material, so that the first impurity-diffused regions 106a and the second impurity-diffused regions 106 are surrounded, and thereby isolated, by the device isolation region 102 and the gate electrodes (112a, 112b) in a plan view. The semiconductor device 100 further contains, over the substrate 101, sidewalls 114 formed respectively on both sides of the first gate electrodes 112a and the second gate electrode 112b, a cover insulating film 120 formed over the entire surface of the substrate 101, an insulating interlayer 122 (insulating film) formed over the cover insulating film 120, and first contacts 124 and second contacts 126 formed in the insulating interlayer 122. The cover insulating film 120 and the insulating interlayer 122 are formed over the first gate electrodes 112a and the second gate electrode 112b, and the first impurity-diffused regions 106a and the second impurity-diffused regions 106b. FIG. 1 does not illustrate the cover insulating film 120 and the insulating interlayer 122.

The first impurity-diffused regions 106a herein are formed on both sides of each first gate electrode 112a. The first contact 124 is provided so as to be connected to the first impurity-diffused region 106a, but is not connected to the first gate electrode 112a. The first contact 124 is therefore a general contact. The second impurity-diffused regions 106b are formed on at least a side of each second gate electrode 112b. The second contact 126 is provided so as to be connected commonly to the second gate electrode 112b and the second impurity-diffused region 106b. The second contact 126 is therefore a shared contact.

In a plan view of the top surface of the insulating interlayer 122, the area of the second contact 126 is larger than that of the first contact 124. In this embodiment, in a plan view of the top surface of the insulating interlayer 122, the first contact 124 has a nearly circular geometry, whereas the second contact 126 has an elliptic geometry.

In this embodiment, each of the first contact 124 and the second contact 126 has a profile such that the taper angle changes at an intermediate position in the depth-wise direction from the surface of the insulating interlayer 122 towards the substrate 101. The intermediate position where the taper angle changes resides more closer to the substrate 101 in the second contact 126, than in the first contact 124. The intermediate position where the taper angle changes in the second contact 126 may reside closer to the substrate 101 than and down below the top surface of the second gate electrode 112b. The intermediate position where the taper angle changes in the first contact 124 may reside more largely away from the substrate 101 than and up above the top surface of first gate electrode 112a.

Taper angle θ₂ of the second contact 126 may be set smaller than taper angle θ₁ of the first contact 124. The taper angle herein is defined by the angle formed between the surface of the substrate 101 and the sidewall of the contact hole, in the insulating interlayer 122 (smaller than or equal to 90°.

In this embodiment, each of the first contact 124 and the second contact 126 has a profile such that the diameter is kept almost constant from the surface of the insulating interlayer 122, down to the intermediate position where the taper angle changes, and is then gradually shrunk from the intermediate position towards the substrate 106.

In this embodiment, the semiconductor device 100 may be configured as a MOSFET (Metal-Oxide-Semiconductor Field-Effect Transistor). The substrate 101 may be configured by a semiconductor substrate such as a silicon substrate.

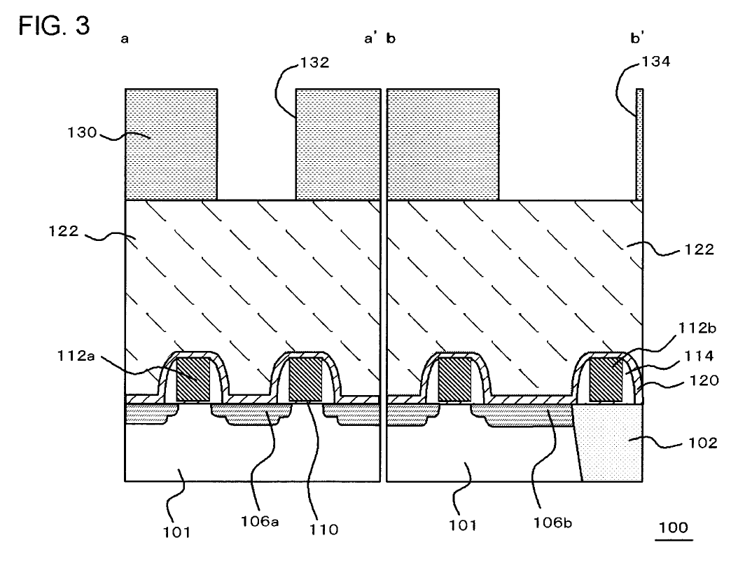

Next, procedures of manufacturing the semiconductor device 100 of this embodiment will be explained, referring to FIG. 1 to FIG. 5. FIGS. 3 to 5 correspond to sectional views taken along lines a-a′ and b-b′ in FIG. 1.

First, the transistors are formed on the substrate 101, by a publicly-known process for manufacturing transistors. More specifically, trenches are formed in the surficial portion of the substrate 101, and the trenches are then filled with a silicon oxide film, for example, to thereby form the device isolation region 102. Next, the gate insulating film 110 is formed over the entire surface of the substrate 101. The gate insulating film 110 may be configured by a film composed of silicon oxide; silicon oxinitride; oxides, oxinitrides or silicates of compounds containing Hf, La, Al or the like; or stacked film of these material films. Next, an electro-conductive film for composing the gate electrodes is formed over the gate insulating film 110. The electro-conductive film for composing the gate electrodes may be configured typically by polysilicon; amorphous silicon; compounds containing a metal such as Ti, Ta, W or the like; or stacked film of these material films. The electro-conductive film and the gate insulating film 110 are then patterned into a predetermined geometry, to thereby form a plurality of gate electrodes containing the first gate electrodes 112a and the second gate electrodes 112b. The level of height of the top surfaces of the first gate electrodes 112a and the second gate electrodes 112b may be set nearly equal. The level of height of the top surfaces of the first gate electrode 112a and the second gate electrode 112b above the surface of the substrate 101 may be adjusted to approximately 50 nm or larger and 150 nm or smaller, for example.

Next, impurity ions are implanted into the substrate 101 using the gate electrodes as a mask, to thereby form SD extension (source/drain extension) regions which configure parts of the first impurity-diffused regions 106a and the second impurity-diffused regions 106b formed later. Next, the sidewalls 114 are formed on both sides of the gate electrodes. The sidewalls 114 may be configured typically by a film of silicon oxide or silicon nitride, or by a stacked film composed of these materials. Impurity ions are implanted again into the substrate 101 using the gate electrodes and the sidewalls 114 as a mask, to thereby form a plurality of impurity-diffused regions including the first impurity-diffused regions 106a and the second impurity-diffused regions 106b.

Although not illustrated herein, a metal silicide layer containing W, Ti, Co, Ni or the like may be formed in the surficial portion of each of the gate electrodes and the impurity-diffused regions.

Next, the cover insulating film 120 and the insulating interlayer 122 are formed in this order, over the entire surface of the substrate 101. The cover insulating film 120 may be configured by a silicon nitride film, for example. The insulating interlayer 122 may be configured by a silicon oxide film, for example. The cover insulating film 120 functions as an etching stopper film when the insulating interlayer 122 is etched. The thickness of the cover insulating film 120 may be adjusted typically to 30 nm or larger and 100 nm or smaller, for example. The thickness of the insulating interlayer 122 may be adjusted typically to 150 nm or larger and 400 nm or smaller, for example.

Thereafter, a resist film 130 having openings, through which contact holes will be formed, is formed over the insulating interlayer 122 by a lithographic process. More specifically, the resist film 130 has a first opening 132 through which a contact hole corresponded to the first contact 124 is formed, and a second opening 134 through which a contact hole corresponded to the second contact 126 is formed (FIG. 3). The second opening 134 herein has an area of opening larger than that of the first opening 132. By adjusting the ratio of areas of openings ((areas of the opening 134)/(the opening 132)) typically to 2.0 or larger, effects of the present invention may fully be exhibited.

Although not illustrated, the resist film 130 may alternatively be configured to contain an anti-reflection coating (ARC), or may still alternatively be configured as a multi-layered resist film in which a lower resist film, an SOG or oxide film, an anti-reflection coating, an upper resist film and so forth are stacked in this order.

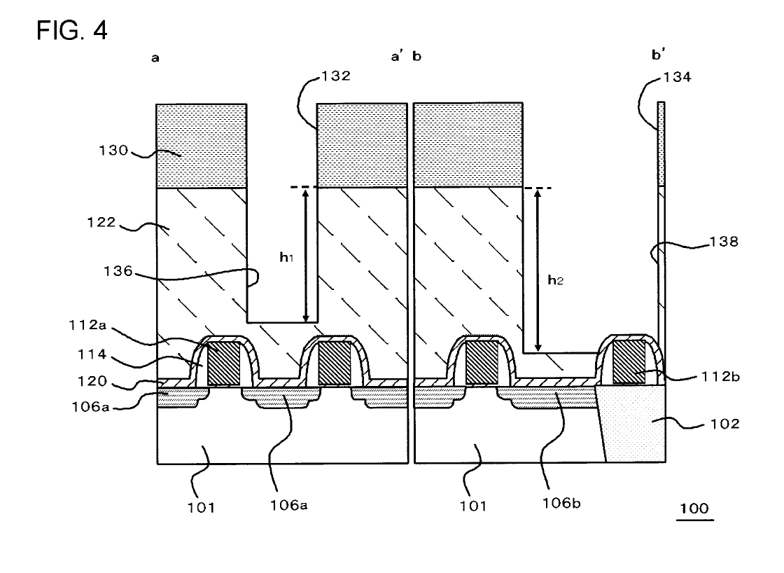

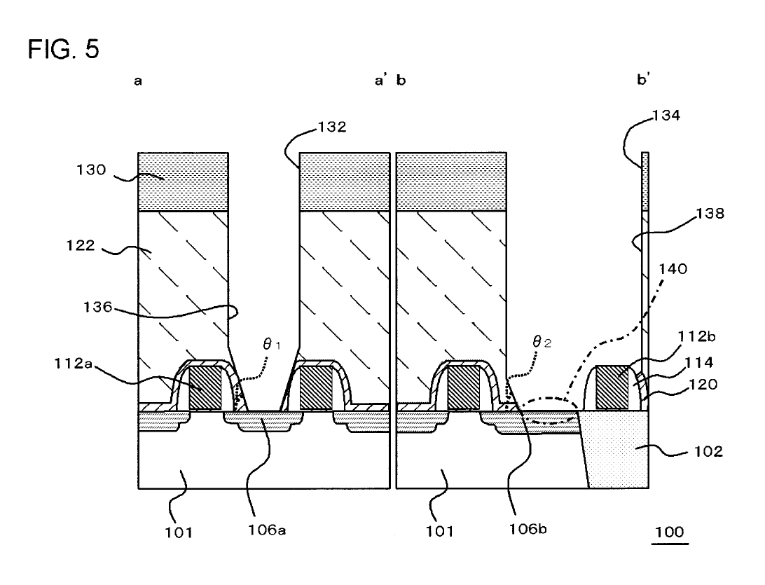

By using the thus-configured resist film 130 as a mask, the insulating interlayer 122 is etched to form the first contact hole 136 and the second contact hole 138 as shown in FIGS. 4 and 5. In this embodiment, using the thus-configured resist film as a mask, the insulating interlayer 122 is firstly etched according to a first etching condition, and then elsewhere in the course of etching, the first etching condition is changed to a second etching condition and the insulating interlayer 122 is etched according to the second etching condition. Under the second etching condition, the diameter of the contact holes is more likely to be shrunk towards the substrate 101, as compared with the first etching condition. The cover insulating film 120 is then removed, if it still remains over the surface of the substrate 101 or on the surface of the second gate electrodes 112b. In this way, the first contact hole 136 and the second contact hole 138 are formed in the insulating interlayer 122, so as to reach the substrate 101.

More specifically, FIG. 4 shows the state where the etching to form the first contact hole 136 and the second contact hole 138 in the insulating interlayer 122 is performed to a certain extent, elsewhere in the course of the etching, according to the first etching condition (FIG. 4). Under the first etching condition, the insulating interlayer 122 is etched so that the first contact hole 136 and the second contact hole 138 formed therein respectively keep constant areas of opening of the first opening 132 and the second opening 134 of the resist film 130. In other words, the first etching condition may be given as the one making the sidewalls of the contact holes nearly vertical.

At this time, the second contact hole 138 is formed more deeply than the first contact hole 136, since the etching rate becomes larger as the area of opening (diameter of hole) increases due to a micro-loading effect. More specifically, depth h₂ of the second contact hole 138 at this stage is larger than depth h₁ of the first contact hole 136. In this embodiment, the etching according to the first etching condition is terminated before depth h₁ of the first contact hole 136 reaches the level of height of the top surface of the first gate electrode 112a, in other words, when the bottom of the first contact hole 136 remains still higher above the top surface of the first gate electrode 112a. Further, the etching according to the first etching condition may be terminated after depth h₂ of the second contact hole 138 comes deeper below the level of height of the top surface of the second gate electrode 112b, in other words, when the bottom of the second contact hole 138 reaches a level deeper than the top surface of the second gate electrode 112b but remains still higher above the substrate 101.

Next, the insulating interlayer 122 is etched according to the second etching condition, to thereby further deepen the first contact hole 136 and the second contact hole 138. Under the second etching condition, the insulating interlayer 122 is etched so that the first contact hole 136 and the second contact hole 138 formed therein gradually reduce the diameter towards the substrate 101. The etching according to the second etching condition is allowed to proceed until the bottoms of the first contact hole 136 and the second contact hole 138 reach the cover insulating film 120 or the substrate 101. The cover insulating film 120 is then removed if it still remains over the surface of the substrate 101 or on the surface of the second gate electrodes 112b, according to an etching condition capable of removing the cover insulating film 120 (FIG. 5). In the course of etching according to the second etching condition, the bottom of the first contact hole 136 reaches the level of height of the first gate electrode 112a, but by virtue of the etching condition at this stage of process effected so as to reduce the diameter of openings, the opening will not be formed on the gate electrode 112a, even if the first opening 132 at the top surface of the insulating interlayer 122 and the first gate electrode 112a seem to be aligned in an overlapped manner in a plan view.

The timing when the etching according to the first etching condition is terminated, and the second etching condition may be set so that the first contact 124 does not cause short-circuiting with the adjacent first gate electrode 112a. In other words, they may be set so that the first contact hole 136 finally formed will not reach the adjacent first gate electrode 112a. For example, by adjusting the second etching condition so that the taper angle of the first contact hole 136 is reduced, the first contact 124 and the first gate electrode 112a may be prevented from causing short-circuiting therebetween. If the taper angle of the first contact hole 136 is kept constant, it may be more advantageous to terminate the etching according to the first etching condition earlier, and to start the etching according to the second etching condition again earlier, in view of preventing short-circuiting between the first contact 124 and the first gate electrode 112a.

The timing when the etching according to the first etching condition is terminated may vary, typically depending on the taper angles of the first contact hole 136 and the second contact hole 138, and may typically be terminated when the bottom of the first contact hole 136 reaches a position higher by 3 nm to 30 nm or around above the top surface of the first gate electrode 112a, and, when the bottom of the second contact hole 138 is lower by 5 nm to 40 nm or around below the top surface of the second gate electrode 112b.

An etching apparatus adoptable herein may be a parallel electrode RIE apparatus, for example. The first etching condition and the second etching condition may be adjustable typically as described below. Any one of the conditions below, or any combination of the conditions below may be adoptable:

(1) pressure is elevated in the first etching condition, than in the second etching condition;

(2) bias power is lowered in the first etching condition, than in the second etching condition; and

(3) a CF-base gas and oxygen are adopted as etching gases both in the first etching condition and the second etching condition, with a flow rate of oxygen in the second etching condition set lower than in the first etching condition.

Thereafter, the resist film 130 is removed typically by ashing. The first contact hole 136 and the second contact hole 138 are then filled with an electro-conductive material, and a portion of the electro-conductive material exposed out of the contact holes is removed typically by CMP, to thereby form the first contact 124 and the second contact 126. The electro-conductive material adoptable herein may be W, Cu and other metals.

### EXAMPLES

The semiconductor device 100 configured similarly to as illustrated in FIG. 1 to FIG. 5 was manufactured. The height of the top surfaces of the first gate electrode 112a and the second gate electrode 112b above the surface of the substrate 101 was adjusted to 70 nm. The thickness of the cover insulating film 120 was adjusted to 30 nm, and the thickness of the insulating interlayer 122 was adjusted to 300 nm. Ratio of areas of the second opening 134 through which a contact hole corresponded to the second contact 126 is formed, and the first opening 132 through which a contact hole corresponded to the first contact 124, was adjusted to 2.3:1.

The first etching condition and the second etching condition were given as listed below:

first etching condition: pressure=70 mTorr, bias power=1500 W, flow rate of C₄F₈=20 sccm, flow rate of Ar=500 sccm, flow rate of O₂=20 sccm; and

second etching condition: pressure=40 mTorr, bias power=2000 W, flow rate of C₄F₈=20 sccm, flow rate of Ar=500 sccm, flow rate of O₂=10 sccm.

The etching according to the first etching condition was terminated when the bottom of the first contact hole 136 becomes higher by 10 nm above the top surface of the first gate electrode 112a, and when the bottom of the second contact hole 138 becomes lower by 20 nm below the top surface of the second gate electrode 112b.

In this example, taper angle θ₁ of the first contact hole 136 herein was 80°, and the diameter of the bottom of the first contact hole 136 was shrunk by 30 nm or around from the diameter of opening of the first opening 132 of the resist film 130.

On the other hand, taper angle θ₂ of the second contact hole 138 was 78°. The thickness of the insulating interlayer 122 remained to be further etched according to the second etching condition, is thinner at the bottom of the second contact hole 138 than at the bottom of the first contact hole 136, so that a smaller effect of shrinkage of the diameter will be exerted on the second contact hole 138. As a consequence, shrinkage of the diameter (longer diameter) of the bottom of the second contact hole 138, from the diameter of opening of the second opening 134 of the resist film 130, was suppressed to as small as 20 nm or around. In this way, the contact region 140 of the second contact 126 with respect to the second gate electrode 112b and the second impurity-diffused region 106b was ensured to a sufficient degree.

Next, effects of the semiconductor device 100 and the method of manufacturing the same of this embodiment will be explained.

Japanese Laid-Open Patent Publication No. H05-283374 describes an exemplary process of concomitantly forming contact holes having different diameters, by two-step etching which include proper-depth etching and extra etching. The publication only aims at suppressing any damages to the lower layer possibly caused in the process of extra etching, and is not intended for controlling the geometry of the contacts, by changing the etching conditions elsewhere in the course of etching as has been described in this embodiment. In order to achieve the geometries of the first contact 124 and the second contact 126 of the semiconductor device 100 as described in this embodiment, it is necessary to appropriately control the etching conditions and the time when the etching condition is changed.

In this embodiment, by adopting the two-step etching conditions, the first contact hole 136 and the second contact hole 138 are initially formed according to the first etching condition under which the taper angle is ensured typically as large as 90° or around, and the etching according to the first etching condition is then terminated at a predetermined point of time. The second contact hole 138 herein having a larger area of opening is formed more deeply than the first contact hole 136. The first contact hole 136 and the second contact hole 138 are then completed by the etching according to the second etching condition under which the taper angle is reduced.

As a consequence, the thickness of the insulating interlayer 122 remained to be further etched according to the second etching condition, is thinner at the bottom of the second contact hole 138, and thereby the amount of shrinkage of the diameter of hole may be moderated in the second contact hole 138 than in the first contact hole 136. On the other hand, the thickness of the insulating inter layer 122 remained to be further etched according to the second etching condition, is thicker at the bottom of the first contact hole 136, and thereby the amount of shrinkage of the diameter may be larger in the first contact hole 136 than in the second contact hole 138.

According to this embodiment, the process-related conversion may therefore be reduced in the second contact 126 which is given as a shared contact, and the diameter of hole may be reduced at the bottom of the first contact 124. In this way, a margin for short-circuiting between the first contact 124 and the first gate electrode 112a may be expanded, while ensuring a sufficient area of contact region 140 of the second contact 126 with respect to the second impurity-diffused region 106b and the second gate electrode 112b, even if the first contact 124 is necessarily formed particularly between a plurality of first gate electrodes 112a narrowly spaced from each other. Stability of yield of the semiconductor device may therefore be improved.

In addition, since the first contact hole 136 and the second contact hole 138 may be formed at the same time by a single photolithographic process, the number of processes may be prevented from increasing, and thereby the cost of manufacturing may be suppressed.

The embodiment of the present invention has been described in the above, referring to the attached drawings, only as one example of the present invention, while allowing adoption of any other various configurations.

For example, in the process of forming the first contact (contact having a smaller area), also an exemplary technique which includes etching according to the first etching condition under which almost vertical profile is obtainable, terminated before the bottom of the opening reaches the top surface of the gate electrode; followed by etching according to the second etching condition (under which a small taper angle is attainable), terminated after the bottom of the opening reaches the level of height down below the top surface of the gate electrode; and further followed by etching according to a third etching condition under which the taper angle of almost 90° is attainable, may be understood as an embodiment of the present invention without departing from the spirit thereof.

It is apparent that the present invention is not limited to the above embodiment, that may be modified and changed without departing from the scope and spirit of the invention.

What is claimed is:

1. A semiconductor device comprising:
a substrate;
a first gate electrode formed over said substrate, while placing a gate insulating film in between;
a second gate electrode formed over said substrate, while placing a gate insulating film in between;
a first impurity-diffused region formed by the side of said first gate electrode;
a second impurity-diffused region formed by the side of said second gate electrode;
an insulating film formed over the entire surface of said substrate over said first gate electrode and said second gate electrode;
a first contact formed in said insulating film, so as to be connected to said first impurity-diffused region, but not to said first gate electrode; and
a second contact formed in said insulating film, so as to be connected commonly to said second gate electrode and said second impurity-diffused region,
each of said first contact and said second contact having a profile such that the taper angle changes at an intermediate position in the depth-wise direction from the surface of said insulating film towards said substrate, and said intermediate position where said taper angle changes residing more closer to said substrate in said second contact, than in said first contact.

2. The semiconductor device as claimed in claim 1,
wherein each of said first contact and said second contact has a profile such that the diameter shrinks from said intermediate position where the taper angle changes, towards the said substrate.

3. The semiconductor device as claimed in claim 1,
wherein each of said first contact and said second contact has a profile such that the diameter is kept constant from the surface of said insulating film, down to said intermediate position where the taper angle changes.

4. The semiconductor device as claimed in claim 1,
wherein said second contact has an area, in a plan view of the surface of said insulating film, larger than that of said first contact.

5. The semiconductor device as claimed in claim 1,
wherein said intermediate position where the taper angle changes in said second contact resides closer to said substrate than and down below the top surface of said second gate electrode.

6. The semiconductor device as claimed in claim 5,
wherein the top surface of said first gate electrode and the top surface of said second gate electrode reside at the same level of height.

7. The semiconductor device as claimed in claim 1,
wherein said intermediate position where the taper angle changes in said first contact resides more largely away from said substrate than and up above the top surface of first gate electrode.

8. The semiconductor device as claimed in claim 7,
wherein the top surface of said first gate electrode and the top surface of said second gate electrode reside at the same level of height.

9. The semiconductor device as claimed in claim 1,
wherein said first contact has a circular geometry and said second contact has an elliptic geometry, in a plan view of the surface of said insulating film.

10. The semiconductor device as claimed in claim 1,
wherein said second contact is a shared contact of SRAM.

11. A method of manufacturing a semiconductor device having a first gate electrode and a second gate electrode formed over a substrate, while placing a gate insulating film in between, respectively; a first impurity-diffused region formed by the side of said first gate electrode; a second impurity-diffused region formed by the side of said second gate electrode; and an insulating film formed over the entire surface of said substrate over said first gate electrode and said second gate electrode;
said method comprising:
forming, over said insulating film, a resist film which has a first opening through which a first contact hole in which a first contact is to be formed so as to be connected to said first impurity-diffused region, but not to said first gate electrode; and has a second opening through which a second contact hole in which a second contact is to be formed so as to be connected commonly to said second gate electrode and said second impurity-diffused region, and
etching said insulating film, using said resist film as a mask, to thereby form said first contact hole and said second contact hole in said insulating film,
in said etching said insulating film, said etching being firstly performed according to a first etching condition and then in the course of said etching, said first etching condition being changed to a second etching condition under which the diameter of hole is more likely to be shrunk towards said substrate, as compared with said first etching condition.

12. The method of manufacturing a semiconductor device as claimed in claim 11,
wherein in said etching said insulating film, said first etching condition is changed to said second etching condition after the bottom of said second contact hole reaches the level of height of the top surface of said second gate electrode.

13. The method of manufacturing a semiconductor device as claimed in claim 11,
wherein in said etching said insulating film, said first etching condition is changed to said second etching condition before the bottom of said first contact hole reaches the level of height of the top surface of said first gate electrode.

14. The method of manufacturing a semiconductor device as claimed in claim 11,
wherein in said etching said insulating film, said etching according to said first etching condition is performed so as to keep the area of opening of said first opening and said second opening constant.

15. The method of manufacturing a semiconductor device as claimed in claim 11,
wherein the area of opening of said second opening is larger than that of said first opening.

16. The method of manufacturing a semiconductor device as claimed in claim 11,
wherein pressure in said first etching condition is larger than that in said second etching condition.

17. The method of manufacturing a semiconductor device as claimed in claim 11,
wherein bias power in said first etching condition is lower than that in said second etching condition.

18. The method of manufacturing a semiconductor device as claimed in claim 11,
wherein a CF-base gas and oxygen are adopted as etching gases both in said first etching condition and said second etching condition, with a flow rate of oxygen in the second etching condition set lower than in said first etching condition.
